(19) United States
(12) Patent Application Publication
(10) Pub. No.: US 2011/0140743 A1
(43) Pub. Date: Jun. 16, 2011

(54) Digital Frequency Generator

(75) Inventor: Andrew Martin Mallinson, Kelowna (CA)

(73) Assignee: ESS Technology, Inc., Fremont, CA (US)

(21) Appl. No.: 12/683,137

(22) Filed: Jan. 6, 2010

Related U.S. Application Data
(63) Continuation of application No. PCT/US10/20149, filed on Jan. 5, 2010.
(60) Provisional application No. 61/285,878, filed on Dec. 11, 2009.
(60) Provisional application No. 61/285,878, filed on Dec. 11, 2009.

(51) Int. Cl. H03B 21/00; G06G 7/16

(52) U.S. Cl. 327/106; 327/356

(57) ABSTRACT

A digital frequency generator is described.

### REFERENCE TO RELATED APPLICATION

This application is a continuation of PCT Application No. PCT/US10/20149, filed 5 Jan. 2010 which claims the benefit of U.S. Provisional Application No. 61/285,878 filed 11 Dec. 2009, and this application claims the benefit of U.S. Provisional Application No. 61/285,878 filed 11 Dec. 2009, all of which are incorporated by reference herein.

### SUMMARY OF THE INVENTION

Various embodiments relate to a digital frequency generator.

An apparatus embodiment includes first clock circuitry, second clock circuitry, and multiplication and addition circuitry:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency different from the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a difference of the first common frequency and the second common frequency, and the phase delay corresponding to the number of clock signals evenly separating the third plurality of clock signals, wherein output components having a frequency equal to a sum of the first common frequency and the second common frequency are mutually canceled in the multiplication and addition circuitry.

In some embodiments, the second clock circuitry is a direct digital synthesis circuit with a filter removing higher frequencies from the second plurality of clock signals.

In some embodiments, the multiplication and addition circuitry includes a zero crossing detector controlled by the multiplication circuitry. Responsive to the zero crossing detector, the second clock circuitry changes the second plurality of clock signals. In some embodiments, the second plurality of clock signals of the second clock circuitry are generated by a phase accumulator and an amplitude/sinusoid look-up-table. In some embodiments, the first clock circuitry is an analog phase shift oscillator. In some embodiments, the first common frequency is less than the second common frequency. In other embodiments, the first common frequency is greater than the second common frequency.

In some embodiments, the first common frequency generates a first part of the third common frequency being an integer multiple of a reference clock frequency, and the second common frequency generates a second part of the third common frequency being a fractional multiple of the reference clock frequency.

In some embodiments, the first clock circuitry is an analog phase shift oscillator. The first common frequency is less than the second common frequency. The first common frequency generates a first part of the third common frequency being an integer multiple of a reference clock frequency. The second common frequency generates a second part of the third common frequency being a fractional multiple of the reference clock frequency. The second plurality of clock signals of the second clock circuitry are generated by a phase accumulator and an amplitude/sinusoid look-up-table. The multiplication and addition circuitry includes a zero crossing detector controlled by the multiplication circuitry. Responsive to the zero crossing detector, the second clock circuitry changes the second plurality of clock signals.

Another apparatus embodiment includes first clock circuitry, second clock circuitry, and multiplication and addition circuitry:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency different from the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a sum of the first common frequency and the second common frequency, and the phase delay corresponding to the number of clock signals evenly separating the third plurality of clock signals, wherein output components having a frequency equal to a difference of the first common frequency and the second common frequency are mutually canceled in the multiplication and addition circuitry.

A further apparatus embodiment includes first clock circuitry, second clock circuitry, and multiplication and addition circuitry:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency equal to the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a sum of the first common frequency and the second common frequency, and half of the phase delay corresponding to the number of clock signals evenly separating the third plurality of clock signals, wherein output components having a zero frequency are mutually canceled in the multiplication and addition circuitry.

An example of the analog phase shift oscillator uses inverters.

Other embodiments are directed to methods.

### BRIEF DESCRIPTION OF THE DRAWINGS

FIG. 1 shows a triple of signals that are evenly separated in phase by 120 degrees, and is an example of a multi-phase clock source that can be combined in the present technology to generate new signals of a different frequency than the frequency of the multi-phase clock source.

FIG. 2 shows computer algebra output that combines two triples of signals to generate a new triple of signals of a new frequency.

FIG. 3 shows computer algebra output that indicates the new triple of signals of FIG. 2 have a new frequency equal to the difference of the frequencies of the original triples of signals, without a frequency sum component.

FIG. 4 is a general expression of the combination of two sets of multi-phase signals of different frequencies, to generate a new set of multi-phase signals having a new frequency.

FIG. 5 is a general expression of the combination of two sets of multi-phase signals of different frequencies, to generate a new set of multi-phase signals having a new frequency, as shown in LISP in the detailed description.

FIG. 6 is a plot of the new set of multi-phase signals having a new frequency generated by LISP, where the new set includes a triple of signals.

FIG. 7 is a plot of the new set of multi-phase signals having a new frequency generated by LISP, where the new set includes a quartet of signals.

FIG. 8 is a plot of the new set of multi-phase signals having a new frequency generated by LISP, where the new set includes a septet of signals.

FIG. 9 is a plot of the new set of multi-phase signals having a new frequency generated by LISP modified to generate the new frequency as the sum of frequencies of the original sets of multi-phase signals, where the new set includes a triplet of signals.

FIG. 10 is a block diagram of a direct digital synthesis circuit using a DAC and filter to generate the new set of multi-phase signals by combining sets of multi-phase signals,

FIG. 11 is a block diagram of a direct digital synthesis circuit using a DAC and a zero crossing detector instead of rather than a filter to generate a high frequency signal by combining sets of multi-phase signals.

FIG. 12 is a graph illustrating an aspect of operation of the direct digital synthesis circuit of FIG. 11, showing how the zero crossing detector causes a change in the output from one sine wave to another sine wave of different phase.

FIG. 13 is a graph showing how the direct digital synthesis circuit of FIG. 11 generates an output clock signal of much higher frequency than any of the original multi-phase signals.

FIG. 14 shows a perfect sinusoid output corresponding to a direct digital synthesis circuit with a filter, such as the circuit of FIG. 10.

FIG. 15 shows a part of a perfect sinusoid input corresponding to a direct digital synthesis circuit with a filter, such as the circuit of FIG. 10.

FIG. 16 shows an imperfect sinusoid output corresponding to a direct digital synthesis circuit without a filter, such as the circuit of FIG. 11.

FIG. 17 shows a part of an imperfect sinusoid input corresponding to a direct digital synthesis circuit without a filter, such as the circuit of FIG. 11.

FIG. 18 shows an imperfect sinusoid output P corresponding to a direct digital synthesis circuit without a filter, such as the circuit of FIG. 11.

FIG. 19 shows a part of an imperfect multi-phase sinusoid X Y Z input for the output of FIG. 18, corresponding to a direct digital synthesis circuit without a filter, such as the circuit of FIG. 11.

FIG. 20 shows an imperfect sinusoid output Q corresponding to a direct digital synthesis circuit without a filter, such as the circuit of FIG. 11.

FIG. 21 shows a part of an imperfect multi-phase sinusoid X Y Z input for the output of FIG. 20, corresponding to a direct digital synthesis circuit without a filter, such as the circuit of FIG. 11.

FIG. 22 shows computer algebra output that indicates the frequency and phase dependence of the new signal P, on the frequency and phase of the original triples of signals.

FIGS. 23-25 show a first multi-phase sinusoid input A B C corresponding to a direct digital synthesis circuit with a filter, such as the circuit of FIG. 10.

FIGS. 26-28 show a second multi-phase sinusoid input X Y Z corresponding to a direct digital synthesis circuit with a filter, such as the circuit of FIG. 10.

FIGS. 29-31 show partial products AX BY CZ from the first multi-phase sinusoid input X Y Z and second multi-phase sinusoid input X Y Z, corresponding to a direct digital synthesis circuit with a filter, such as the circuit of FIG. 10.

FIG. 32 shows a perfect sinusoid output P from the sum of the partial products AX BY CZ, corresponding to a direct digital synthesis circuit with a filter, such as the circuit of FIG. 10.

FIGS. 33-35 show a first multi-phase sinusoid input A B C corresponding to a direct digital synthesis circuit with a filter, such as the circuit of FIG. 10.

FIGS. 36-38 show a second multi-phase sinusoid input X Y Z corresponding to a direct digital synthesis circuit with a filter, such as the circuit of FIG. 10.

FIGS. 39-41 show partial products AY BZ CX from the first multi-phase sinusoid input X Y Z and second multi-phase sinusoid input X Y Z, corresponding to a direct digital synthesis circuit with a filter, such as the circuit of FIG. 10.

FIG. 42 shows a perfect sinusoid output Q from the sum of the partial products AY BZ CX, corresponding to a direct digital synthesis circuit with a filter, such as the circuit of FIG. 10.

FIGS. 43-45 show a first multi-phase sinusoid input A B C corresponding to a direct digital synthesis circuit with a filter, such as the circuit of FIG. 10.

FIGS. 46-48 show a second multi-phase sinusoid input X Y Z corresponding to a direct digital synthesis circuit with a filter, such as the circuit of FIG. 10.

FIGS. 49-51 show partial products AZ BX CY from the first multi-phase sinusoid input X Y Z and second multi-phase sinusoid input X Y Z, corresponding to a direct digital synthesis circuit with a filter, such as the circuit of FIG. 10.

FIG. 52 shows a perfect sinusoid output R from the sum of the partial products AZ BX CY, corresponding to a direct digital synthesis circuit with a filter, such as the circuit of FIG. 10.

FIGS. 53-55 show a first multi-phase sinusoid input A B C corresponding to a direct digital synthesis circuit without a filter, such as the circuit of FIG. 11.

FIGS. 56-58 shows a second multi-phase imperfect sinusoid input Xp Yp Zp corresponding to a direct digital synthesis circuit without a filter, such as the circuit of FIG. 11.

FIG. 59 shows an imperfect sinusoid output P from the sum of the partial products AXp BYp CZp, corresponding to a direct digital synthesis circuit with a filter, such as the circuit of FIG. 11.

FIGS. 60-62 shows a second multi-phase imperfect sinusoid input Xq Yq Zq corresponding to a direct digital synthesis circuit without a filter, such as the circuit of FIG. 11.

FIG. 63 shows an imperfect sinusoid output Q from the sum of the partial products AYq BZq CXq, corresponding to a direct digital synthesis circuit with a filter, such as the circuit of FIG. 11.

FIGS. 64-66 shows a second multi-phase imperfect sinusoid input Xr Yr Zr corresponding to a direct digital synthesis circuit without a filter, such as the circuit of FIG. 11.

FIG. 67 shows an imperfect sinusoid output R from the sum of the partial products AZr BXr CYr, corresponding to a direct digital synthesis circuit with a filter, such as the circuit of FIG. 11.

### DETAILED DESCRIPTION

Virtually all electronic systems require a clock. A clock is a regular event, typically a regular digital signal within the electronic system that mediates internal operations allowing time for asynchronous events to come back into synchrony and so make meaningful operations and avoid mistaken interpretations of transient and incorrect results.

Within analog systems a clock may do more. The clock may be the source of a radio signal transmitted or the source of a local oscillator that determines the received signal within a radio or the reference frequency used by a digital music player.

The primary characteristic of a clock signal is its frequency. Relevant considerations include: how precise is that frequency—to what degree does the actual frequency correspond to the requested frequency—and, how accurate are the timings of the edges—does each fall precisely on the mathematically correct time point? These considerations are answered by the resolution achievable in the frequency setting, and the jitter or phase noise of the clock source.

Ultimately any clock source operates relative to another, because electronic devices cannot have any “knowledge” of absolute time. So a reference input clock of, for example, 10 MHz may be provided from which the clock generator is expected make other related clock signals. For example, given that its input is a 10 MHz reference clock, the clock generator may create a 123.456789 Mhz output clock. The degree to which the digits in the specification are used, determines the resolution. The specification just given assumes the clock generator is able to make 100 Mhz to 1 Hz of resolution, or a resolution of 1 part in 10⁸.

Phase locked loops (PLLs) are commonly used since these are devices with an adjustable free running oscillator that is controlled by a feedback loop such that its oscillation frequency divided by an integer, say M, is equal to the reference frequency divided by another integer, say N. The oscillation frequency will then be M/N times the input reference clock frequency.

In other systems of clock generation a direct digital synthesis (DDS) of the clock may be used. This is a technique where digital values representing a sinusoidal signal are generated on each edge of the input reference clock. If then applied to a digital to analog converter (DAC) and filtered, the resulting analog sine wave can be of arbitrarily high resolution.

In the present technology, a high resolution clock source is created given a clock source of lower resolution by making precise frequency shifts of that lower resolution clock source. The disclosed technology uses a digital source and a DAC, but does not require a filter. The technology makes use of trigonometric identities that are shown to exist in signals represented as three or more simultaneous sinusoids with fixed phase relations to each other. After processing in the multi-phase signal domain, the zero crossing of the multi-phase signal may be used to create a single phase clock of substantially higher frequency than the multi-phase signal.

In the present technology a high speed multi-phase clock source is constructed with high resolution in frequency setting. The disclosed technology operates upon multiphase sinusoidal signals which maintain a fixed phase relation to each other. For example, three phases each in 120° relation to one another is an example of such signals. Such signals may be generated and frequency shifted without creation of unwanted other frequencies. Such signals, having multiple phases in fixed relation, can be combined to create a single phase clock that is many times faster than each of the individual phases. In contrast, operation on single phase sinusoidal signals generally creates unwanted other frequencies. For example, if the difference frequency is required, there will be an unwanted sum frequency and vice-versa. Also, in operations on pairs of sinusoidal signal in quadrature, typically a single phase output results and the created frequency, not a dual phase output; so the opportunity to preserve a multi-phase signal is lost.

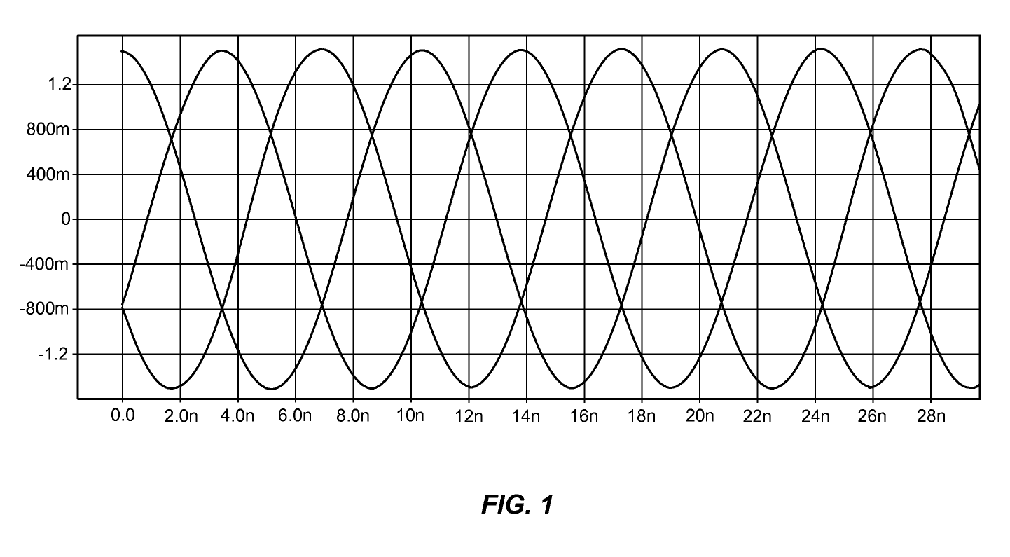

FIG. 1 is an example of a triple of signals, each in 120° phase relation to each other. The technology is not restricted to three phases, and works equally well in any number of phases greater than two. However, odd numbers of phases, when combined into one clock signal, generate a higher output frequency since they have separate (non-overlapping) zero crossings.

### Example with Three Phases

A three phase example is characterized by these expressions: sin(x), sin(x+2/3pi) and sin(x+4/3pi). Or in degrees: sin(x), sin(x+120′), and sin(x+240°).

The basic principle exploits the following trigonometric identity. Given that:

A=sin(w1), B=sin(w1+pi*2/3) and C=sin(w1+pi*4/3)
represent one triple of three signals in 120° relation to each other operating at frequency ‘w1’, and

X=sin(w2), Y=sin(w2+pi*2/3) and Z=sin(w2+pi*4/3)

represent a second triple of signals in 120° relation to each other, but operating at frequency ‘w2’ then a triple of signals P, Q and R constructed as:

P=A*X+B*Y+C*Z, Q=A*Y+B*Z+C*X and R=A*Z+B*X+C*Y

which are also a triple of three signals at 120° relation to each other, but now operating at a frequency of ‘w2−w1’.

A first important aspect of this technology is that, that there is no approximation in this relation. Specifically there is no second or other unwanted frequency other than the desired ‘w2−w1’. A second important aspect of this technology is that, three signal emerge from this operation, which are in 120° relation to each other, similar to the input signals.

Operations on single phase signals fail to meet the first aspect. Operations on dual phase signals fail to meet the second aspect. Accordingly, three is the minimum number of signals that meet both aspects.

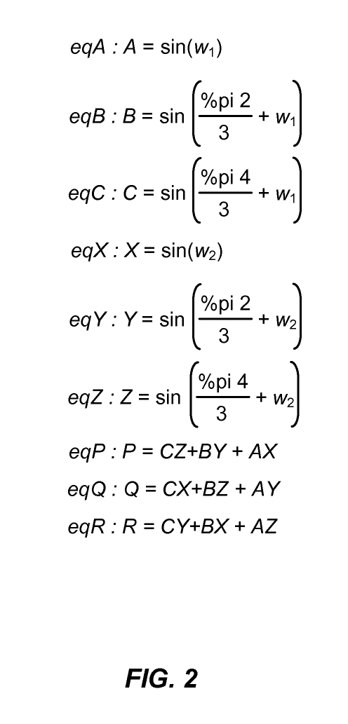

Consider three sets of signals shown in FIG. 2.

A first set of signals is expressed in three quantities: eqA, eqB and eqC which define the first signal frequency. These are quantities all at frequency w1 and each is 120° in relative phase to the others. (120° is the same as pi*2/3). The notation used here is that of Maxima, a computer algebra system. The constant pi is represented as ‘% pi’.

The second set of signals is defined by eqX, eqY and eqZ and is seen to be a similar set of quantities also 120° phase offset, but now at frequency w2.

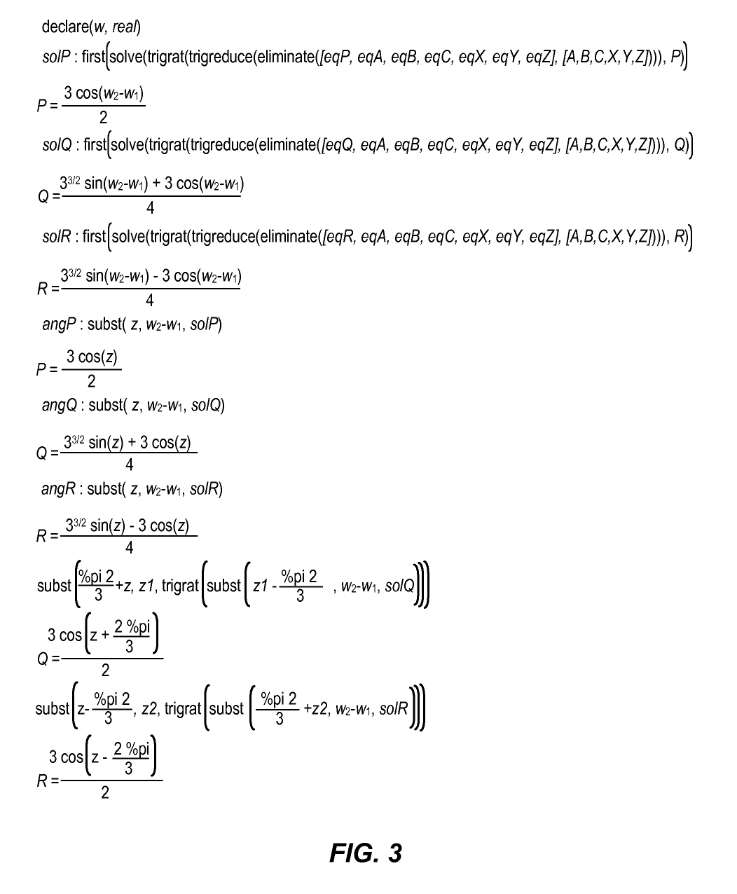

A third set of signals eqP, eqQ and eqR is defined as in FIG. 2. The solution of these equations represents once again a set of three signals in 120° relation to each other, but now at a frequency of w2−w1. The frequency has been shifted by the operation of eqP, eqQ and eqR. The complete proof of this is shown using Maxima on FIG. 3.

In FIG. 3, the output shows that P is 3/2 of a cosine wave at frequency z (which is equal to w2−w1) and that Q and R are 3/2 of a cosine wave also at frequency z, but with phase offsets of plus 2/3pi and minus 2/3pi. The phase relation is maintained and a theoretically ideal frequency shift occurs.

In FIG. 3, the apparently redundant substitution of Z1 for Z immediately followed by its removal, works around a limitation of Maxima.

Generalization to More than Three Phases

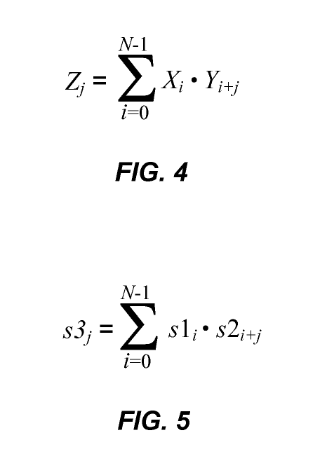

The prior example and the algebraic solution presented are for the three phase case. But the technology works in any number of phases. In general the operation on multiple phases of any order is shown in FIG. 4.

In FIG. 4, N is the number of phases, the index operation (i+j) is modulo N, Z is the output vector of output phases, X and Y are the vectors of input phases.

A complete generalization to any order is represented by this LISP code:

(defun show-dfg-N (N &key (f1 100M) (f2 3.45M) (tmax 0.1u)
(tstep 100p))

(let ((s1 (make-array N :initial-element nil))

(s2 (make-array N :initial-element nil))
(s3 (make-array N :initial-element nil)))

(labels ((advance (time s f)

(loop for i below N

as value = (sin (+ (/ (* i 2 pi) N) (* 2 pi f time)))
do (push value (aref s i))))

(calculate-dfg ( )
(loop for i below N

do
(push
(loop for j below N
sum (* (car (aref s1 j)) (car (aref s2 (mod (+ i j)
N))))) (aref

s3 i)))))

(loop

for time below tmax by tstep
do
(advance time s1 f1)
(advance time s2 f2)
(calculate-dfg)
finally
(plot (coerce s3 ′list) tstep “DFG”)))))

The preceding code example works as follows: the parameter ‘N’ is the number of phases required, the parameter ‘f1’ defaults to 100 MHz and is the frequency of the first set of phases, the parameter ‘f2’ defaults to 3.45 MHz and is the frequency of the second set of phases. The parameter ‘tmax’ is the time limit of the simulation model and the parameter ‘tstep’ is the time-step taken in the simulation.

The locally created variables (in the ‘let’ clause) are each an array of length ‘N’. The array variable ‘s1’ captures all the state of the ‘N’ phases operating at ‘f1’, similarly, ‘s2’ captures all the state of the ‘N’ phases operating at ‘f2’. These are the state variable arrays. The array variable ‘s3’ captures all the state of the synthesized output ‘N’ phases. Two lexically defined functions (the clauses of the ‘labels’) show clearly the operation of the technology. The first function ‘advance’ accepts the current simulation time, the state variable to use, and the frequency represented for that state variable. It then calculates the ‘N’ phases of that variable and pushes the result onto a push-down list of results stored in the state variable. So ‘advance’ encapsulates the act of creating the input phases for any value of ‘N’.

The second function ‘calculate-dfg’ is part of the technology. It implements the formula of FIG. 5 as described above. In detail it first iterates over the ‘N’ elements of the output state s3 (with the index T), within this iteration it iterates over the elements of the input states s1 and s2 (with the index T). For each value of ‘i’, the outer iteration, it forms the sum of products of elements from the input state variables. The current value of the state variable is accessed with the (car(aref s1 j)) form since the array stores a complete history of values in a push down stack and hence the ‘car’ is the last of the history. The correct state variable of ‘s2’ is accessed by the modulus operation (car (aref s2(mod(+ij)N))) which reduces the address calculation (+ij) to modulo ‘N’ as required.

The main ‘loop’ body of the function performs the simulation over time; it calls the lexically defined functions ‘advance’ and ‘calculate’ as needed and runs with time-step ‘tstep’ to the maximum time ‘tmax’.

At the end of the time simulation the ‘finally’ clause executes and calls for the ‘plot’ function on the s3 state variable. The ‘plot’ function is an extension to LISP used to visualize data—calling this function will show us the complete history of the ‘s3’variable. The ‘plot’ function accepts a list of lists as its first argument, which become the ‘y’ values of the plot. The second argument to ‘plot’ is the time step and the third argument is the name of the plot to create. ‘s3’ is coerced into a list of list in order to provide the ‘y’ values.

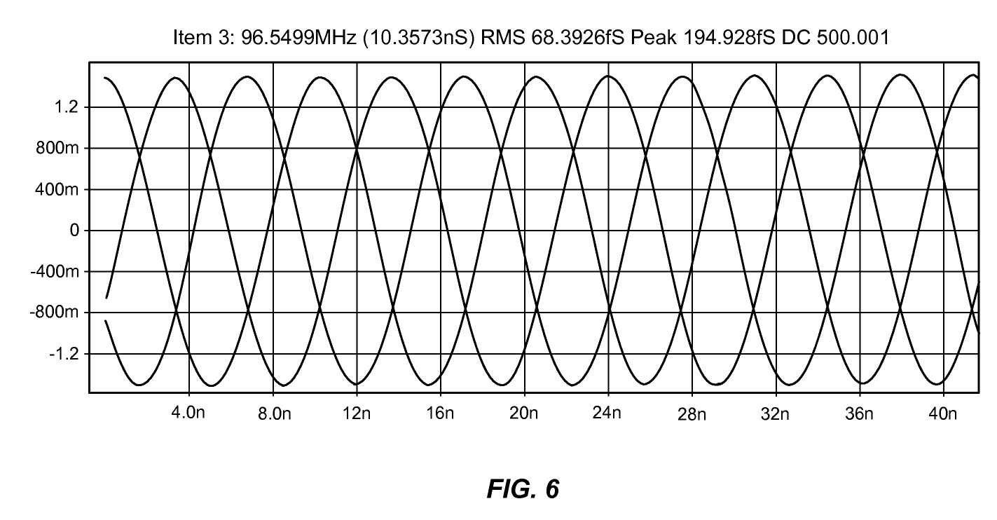

The call to (show-dfg-N 3) creates the plot of FIG. 6. The three traces are the phases of the ‘s3’ variable—each is 120° to the others as expected. Note that the output frequency (visible in the text above the plot) shows that the measured frequency is 96.5499 MHz. This is as expected since ‘f1’ was 100 MHz and ‘f2’ 3.45 Mhz—this should have created 96.55 Mhz—which it did to within the error of the frequency measurement.

Also, note the zero crossings of the phases: each crosses zero independently, and, when each zero crossing creates a pulse output, these pulses are created at a rate of six times the 96.55 MHz rate. The generation of pulses on the zero crossings is not required to make use of the technology. The technology includes the processing of sets of multi-phase signals to create a sum or difference output signal or sets of signals. However, when used to generate a clock source, the zero crossing and the multi-phase nature of the output created, can be used to create relatively high speed clocks. In this example, a clock of 6*96.55 Mhz or 579. MHz results.

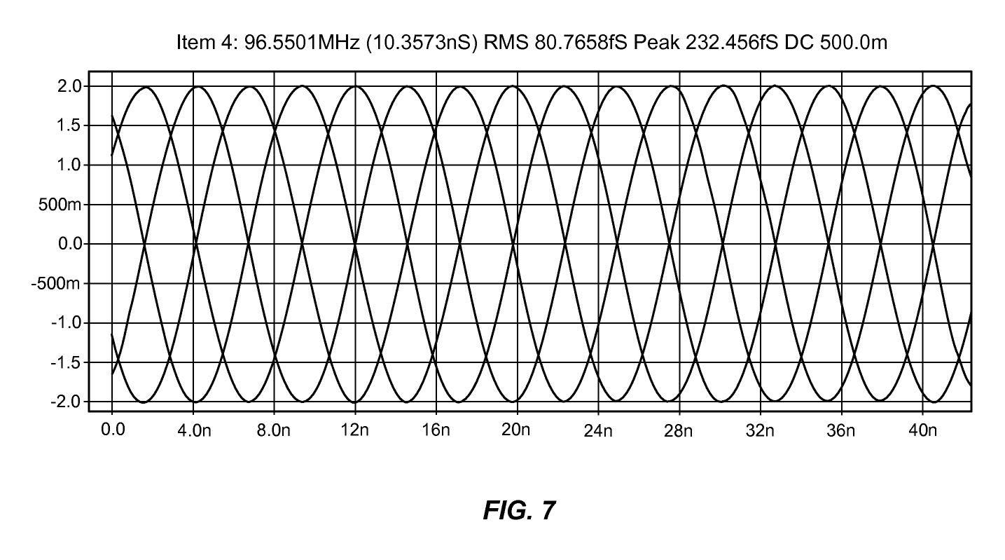

The call to (show-dfg-N 4) creates FIG. 7.

Again the output frequency is correct (being 96.55 MHz) and the four phases are clearly shown. However, note that despite the additional phase, there are no more zero crossings available. In fact there are less, because pairs of the phases are crossing at the same time.

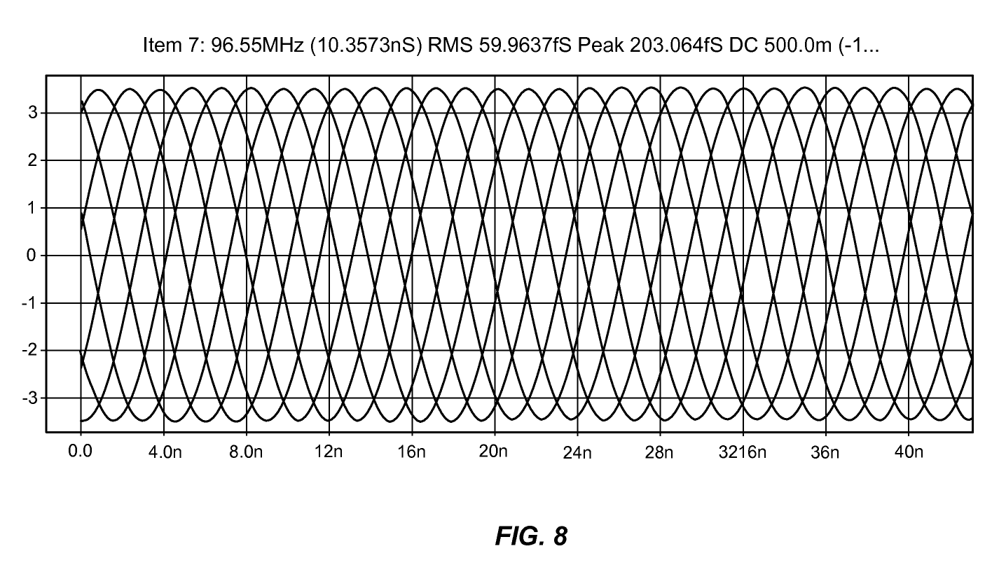

Finally, FIG. 8 is (show-dfg-N 7).

Odd numbers create more zero crossings and this example has a total of 14 zero crossings in the 96.55 MHz cycle. Clearly, all versions of the technology generate “pure” sinusoidal outputs at the frequency difference without artifact. Odd numbers of phases are more useful to exploit the zero crossings, and three is the minimum number of phases for which this technology operates.

Some embodiments make the difference of two frequencies rather than the sum. Other embodiments make the sum, as illustrated by the following underlined modification to the code:

(calculate-dfg ( )

(loop for i below N
do
(push
(loop for j below N

sum (* (car (aref s1 j)) (car (aref s2 (mod (− i j) N)))))

(aref s3 i)))))

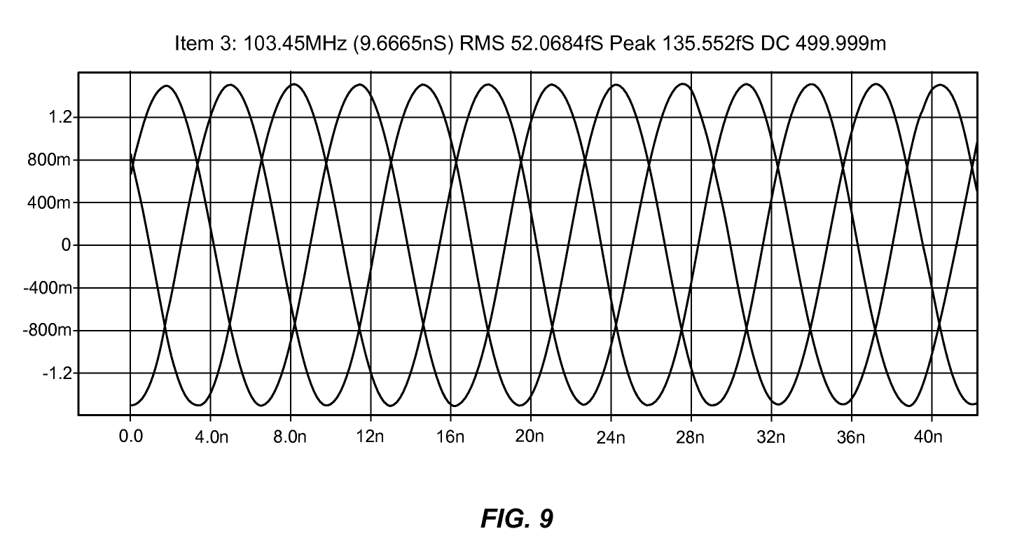

That is, subtract j from i rather than add, then FIG. 9 results.

Note the frequency has now added creating 103.45 Mhz. Consequently, a second degree of freedom exists in the design and both addition and subtraction are embodiments.

Practical Implementation in an Electronic System Using DDS to Generate the Second Signal in Three Phases

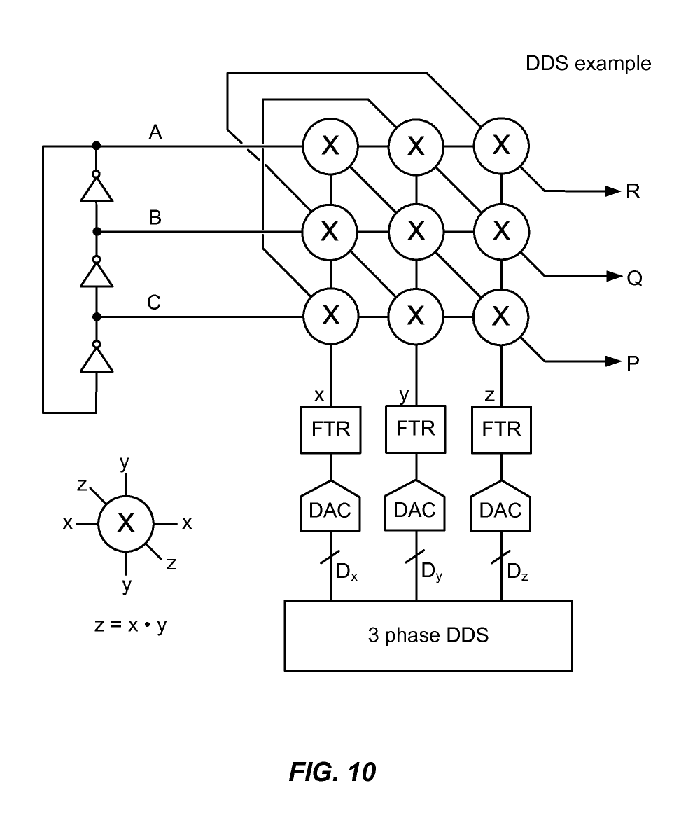

As shown the technology is not restricted to three phases—any number greater than two is an embodiment. For clarity, these examples work with three phases, although embodiments extend to the examples as applied to more phases. This first example of FIG. 10 is a direct digital synthesis using a DAC and filter employed to generate the second multi-phase signal. The first multiphase signal originates in a multi-phase oscillator schematically represented as the three “inverters” on the left side. These three “inverters” are analog elements with sufficient gain and phase to oscillate with 120° phase difference. In this example the A/B/C signals are operating at 100 MHz.

The lower part shows the DDS section. The DDS section creates a precise and relatively low frequency set of 120° related signals. The DDS is making 3.45 MHz. The technology uses the multipliers and implied adders. The circular element is the multiplier, which accepts a signal ‘x’ on the horizontal wire, a signal ‘y’ on the vertical wire and creates an output ‘z’ on the diagonal wire. When a ‘z’ wire is connected together an assumed addition is taking place. For example, the diagonal wire from top left to bottom right is forming P=A·X+B·Y+C·Z. As shown the nine multipliers of FIG. 10 are implementing the “Example with Three Phase” discussed previously.

The filters remove the higher signals present in the DAC output.

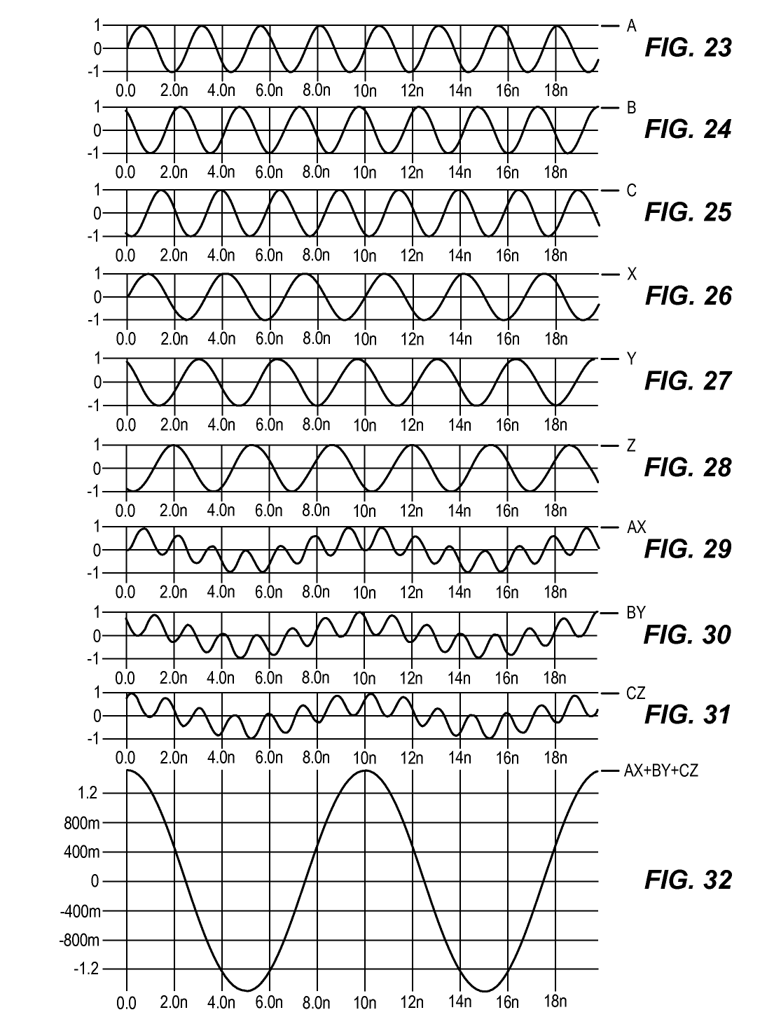

FIGS. 23-52 show examples of input and output signals for the direct digital synthesis circuit with a filter, such as the circuit of FIG. 10.

FIGS. 23-25 show a first multi-phase sinusoid input A B C corresponding to a direct digital synthesis circuit with a filter, such as the circuit of FIG. 10.

FIGS. 26-28 show a second multi-phase sinusoid input X Y Z corresponding to a direct digital synthesis circuit with a filter, such as the circuit of FIG. 10.

FIGS. 29-31 show partial products AX BY CZ from the first multi-phase sinusoid input X Y Z and second multi-phase sinusoid input X Y Z, corresponding to a direct digital synthesis circuit with a filter, such as the circuit of FIG. 10.

FIG. 32 shows a perfect sinusoid output P from the sum of the partial products AX BY CZ, corresponding to a direct digital synthesis circuit with a filter, such as the circuit of FIG. 10.

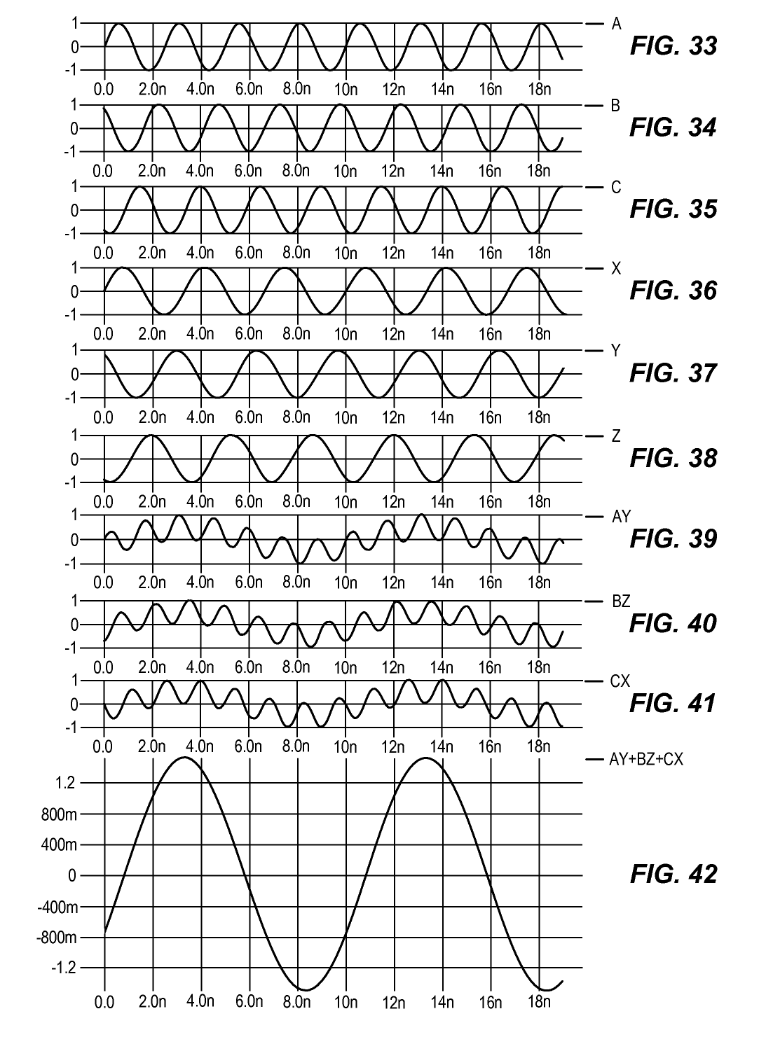

FIGS. 33-35 show a first multi-phase sinusoid input A B C corresponding to a direct digital synthesis circuit with a filter, such as the circuit of FIG. 10.

FIGS. 36-38 show a second multi-phase sinusoid input X Y Z corresponding to a direct digital synthesis circuit with a filter, such as the circuit of FIG. 10.

FIGS. 39-41 show partial products AY BZ CX from the first multi-phase sinusoid input X Y Z and second multi-phase sinusoid input X Y Z, corresponding to a direct digital synthesis circuit with a filter, such as the circuit of FIG. 10.

FIG. 42 shows a perfect sinusoid output Q from the sum of the partial products AY BZ CX, corresponding to a direct digital synthesis circuit with a filter, such as the circuit of FIG. 10.

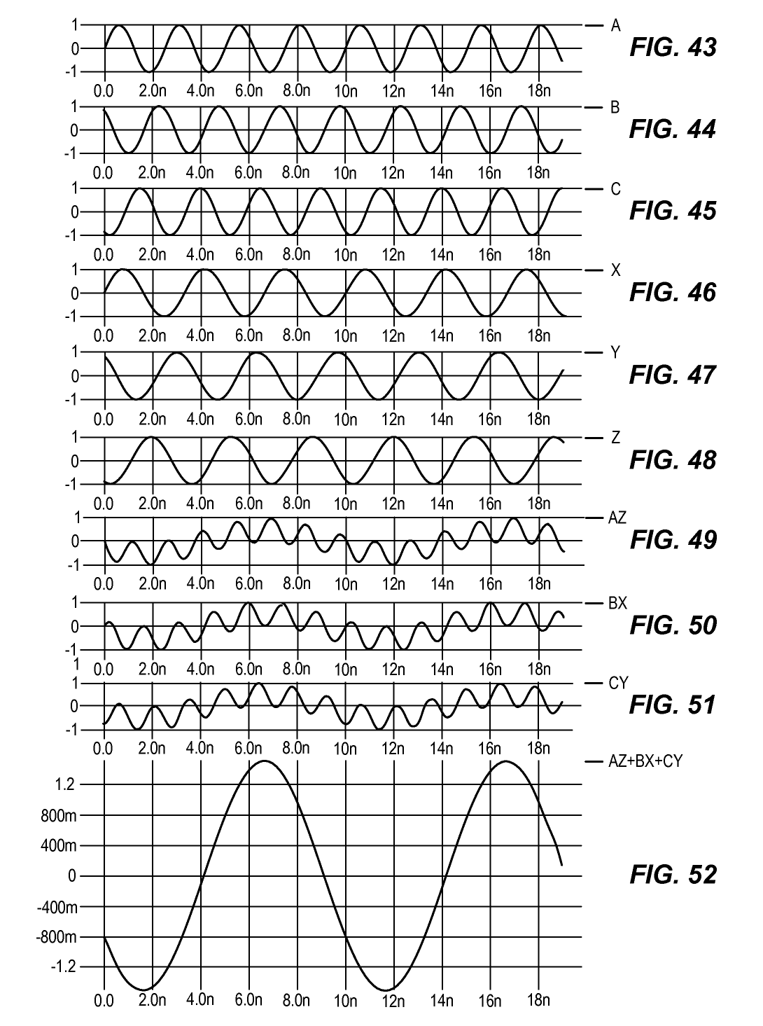

FIGS. 43-45 show a first multi-phase sinusoid input A B C corresponding to a direct digital synthesis circuit with a filter, such as the circuit of FIG. 10.

FIGS. 46-48 show a second multi-phase sinusoid input X Y Z corresponding to a direct digital synthesis circuit with a filter, such as the circuit of FIG. 10.

FIGS. 49-51 show partial products AZ BX CY from the first multi-phase sinusoid input X Y Z and second multi-phase sinusoid input X Y Z, corresponding to a direct digital synthesis circuit with a filter, such as the circuit of FIG. 10.

FIG. 52 shows a perfect sinusoid output R from the sum of the partial products AZ BX CY, corresponding to a direct digital synthesis circuit with a filter, such as the circuit of FIG. 10.

Practical Implementation in an Electronic System Using Filter-Less DDS to Generate the Second Signal in Three Phases

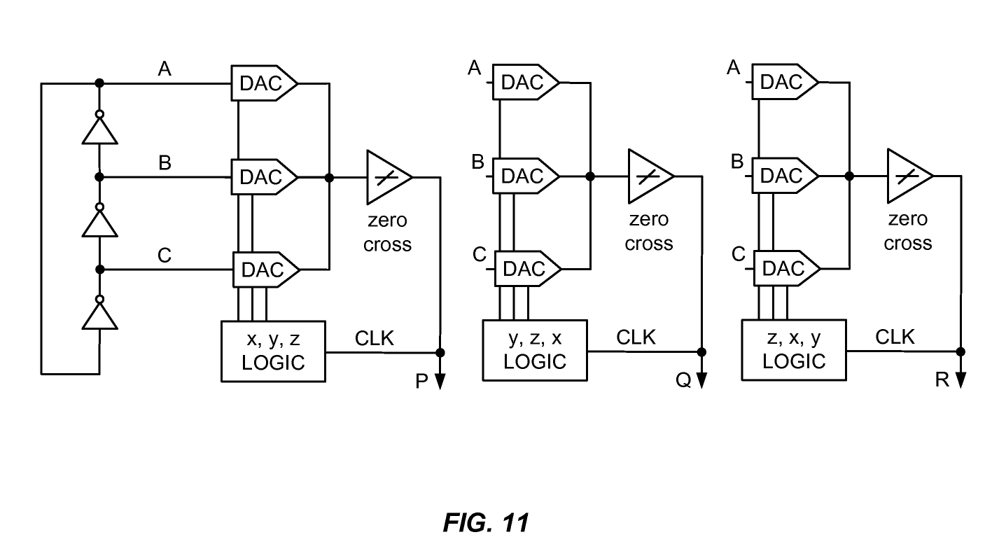

FIG. 11 replaces the explicit multiplier with a multiplying DAC. The left side input to the DAC is an analog signal, the same A,B,C signals from the oscillator as in FIG. 10. The bottom input to the DAC is a digital input port representing a signed number. The right output of the DAC is a signal equal to the left side input multiplied by the digital number. Again, where three DAC right hand side outputs connect together a summation is implied. The analog sum is applied to a zero-crossing detector—whenever zero is crossed, either positive or negative going, a clock pulse is generated to the corresponding logic. The logic is that of a DDS system (but without filter) and the new values of x,y,z are produced in response to the clock from the zero crossing detector. Note that the three DDS logic elements are all generating the x,y,z signal, but the routing to the DACs is not the same. Once again the DAC connections make use of the technology for the signals in the “Example with Three Phase” discussed previously.

The x,y,z logic; the y,z,x logic; and the z,x,y logic are a phase accumulator (modulo-M counter) combined with an amplitude/sinusoid LUT. Each of the x,y,z logic; the y,z,x logic; and the z,x,y logic generate 3 digital representations of a sinusoid staggered by an equal phase. The different orderings of the letters x,y,z; y,z,x; and the z,x,y correspond to different orderings of the 3 clock phases. The zero-crossing detector is fed into the clock input of the x,y,z logic; the y,z,x logic; and the z,x,y logic, such that the zero crossing detector increments the phase accumulator (modulo-M counter) within the x,y,z logic; the y,z,x logic; and the z,x,y logic.

Three state variables are maintained in each of three blocks of logic. A modulo-M counter is associated with each state variable. Upon receipt of a zero crossing the three state variables are incremented modulo-M. A look-up table translates the state variables to a sinusoid, there being one cycle of the sinusoid over the M states. Each of the three state variables differs in value by nominally ⅓ of M. Consequently, from each of the three blocks of logic, three phases are provided that are 120 deg apart that advance by a certain phase increment per each of the zero crossings.

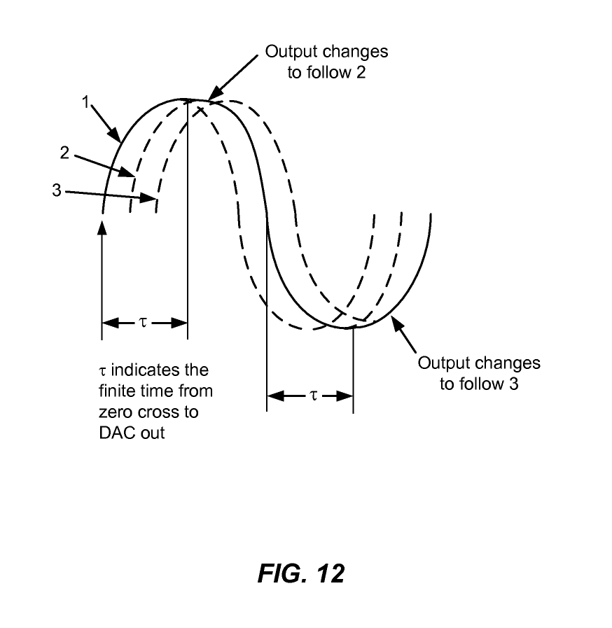

As a consequence of the DACs changing on each zero crossing the signals P/Q/R do not follow a simple sine wave. Rather, the signals follow FIG. 12. Some short time after the zero crossing is detected the DDS logic causes the DAC to change state.

This in turn causes the output (for example the P signal) to change trajectory. The output would have followed the sine wave labeled ‘1’ but as a result of the DAC change the phase is adjusted to follow the sine wave ‘2’. The next zero crossing is therefore delayed. When that delayed zero crossing eventually occurs, the DAC's adjust again, causing the trajectory to change to that of sine wave ‘3’. And so forth. The zero crossings correspond to a signal at some synthesized frequency different from the A/B/C frequency. This embodiment achieves a frequency shift in the timing of the zero crossings at the output.

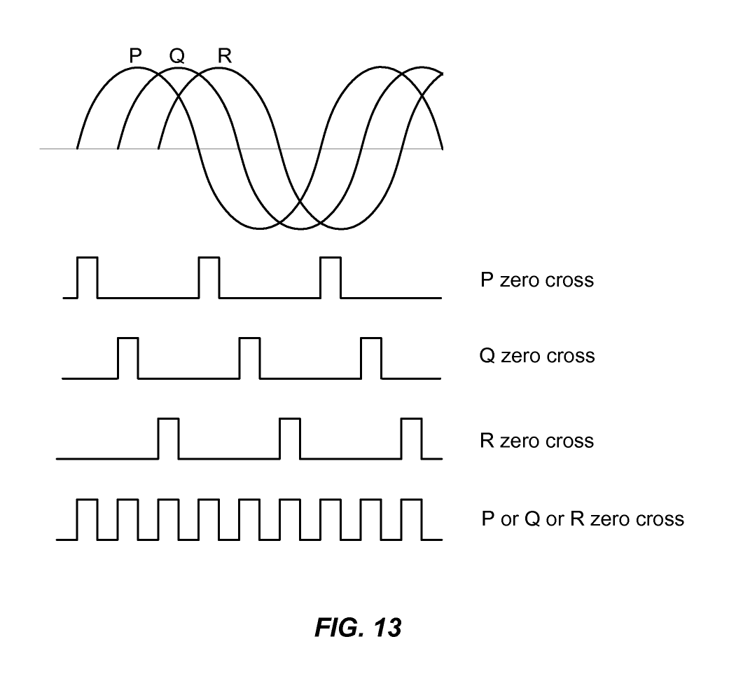

The output signals P/Q/R generated by this last example are pulses initiated on the zero crossing of the summed DAC output signals. These pulse may be made short, for example, if the sine wave synthesized and adjusted as described has zero crossings every 2 nS, (which means that it is a 250 MHz signal) the pulse duration can be significantly less than half of this number, for example, 300 pS. As shown in FIG. 13, in this case the logical OR of the pulses from P Q and R generates a pulse six times for every cycle of the A/B/C signals.

In this second practical implementation, the x,y,z logic; the y,z,x logic; and the z,x,y logic correspond to a three phase clock as follows.

The first implementation, where DDS is used to make the X,Y,Z signals, shows that the network makes for example, P=A·X+B·Y+C·Z where all are sinusoidal signals. The zero crossings of these signals are used to make a clock. Given the primary interest in the zero crossings, the filter of the first implementation can be omitted, as follows.

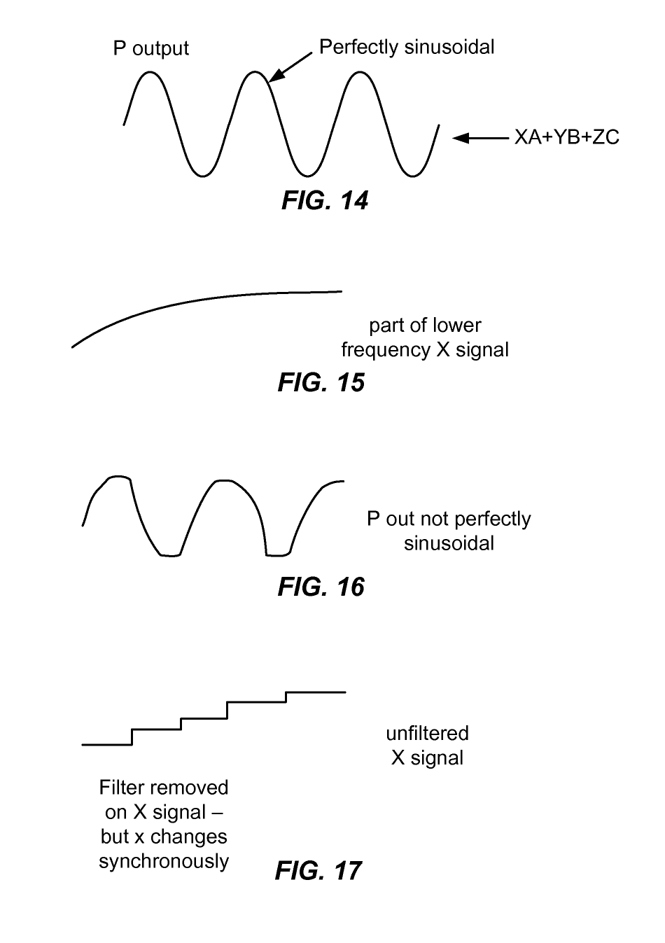

FIG. 14 shows the filtered P signal output. FIG. 15 shows part of the much lower frequency filtered X signal input. More generally, the signals of the P, Q, and R signal outputs, and the smooth filtered signals of the X, Y, and Z signal inputs, result from the smooth filtering by the filter of the DDS.

FIG. 16 shows the unfiltered P signal output. FIG. 17 shows part of the much lower frequency unfiltered X signal input. Now the P output (and the Q and R) are not sinusoidal, and instead move from one sine wave to another, as shown in FIG. 12. Even though not sinusoidal, the zero crossings are still perfectly even. Although the generation of the X (and the Y and the Z) signal are now synchronous and unfiltered, they remain stable throughout the zero crossing.

The x,y,z logic; the y,z,x logic; and the z,x,y logic blocks which generate the X, Y, and Z signals are discussed as follows. The # of wires decreases from 3, to 2, to 1, as the logic connects to the C signal DAC, the B signal DAC, and the A signal DAC, because the wires are passing “behind” the DACs on their to the DACs above.

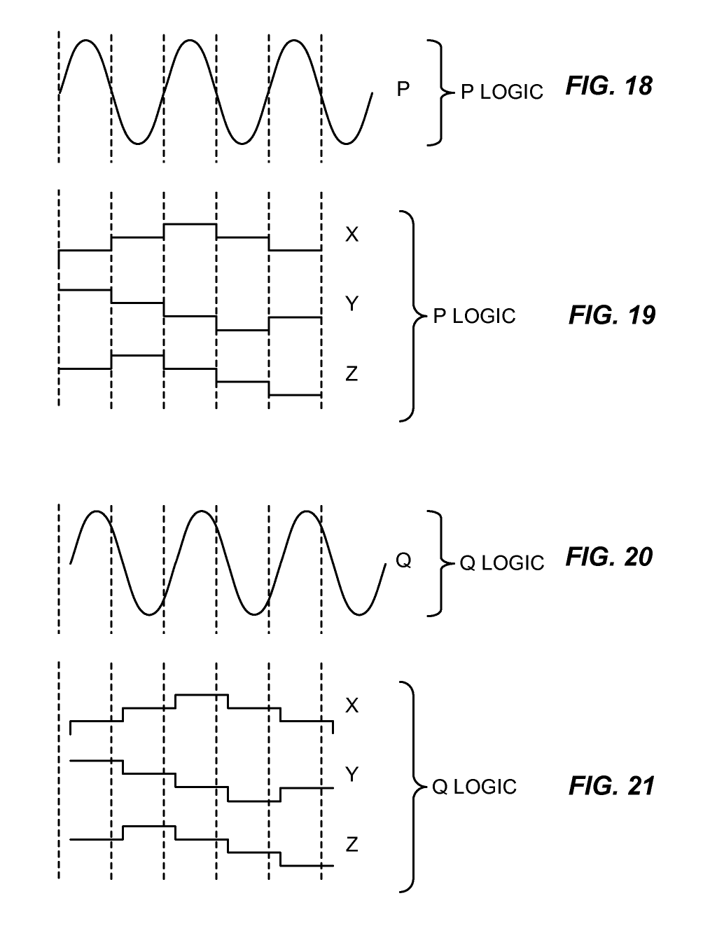

FIGS. 18 and 20 shows signals P and Q respectively. Signal R is similar. The X, Y, and Z signals are generated by the zero crossings themselves, and being unfiltered, show step like changes just after each zero crossing. The X,Y,Z for the Q signal are not quite the same as the X,Y,Z for the P signal, since they change on the zero crossings of the Q signal rather than the zero crossings of the P signal. FIGS. 19 and 21 respectively show the X,Y,Z signals for the P logic, and the X,Y,Z signals for the Q logic. The X,Y,Z signals for the R logic are similar. Accordingly, there are three separate logic blocks each having a separate X,Y,Z output. The order of the letters is changed, (i.e. xyz, yzx and zxy) solely as a result of the fixed order of the A,B,C signals in the drawing. Equivalently, all the logic blocks may be shown as xyz, and the order of the A,B,C signals rotated. Such rotation maintains consistency with the formulas: P=A·X+B·Y+C·Z, and Q=B·X+C·Y+A·Z.

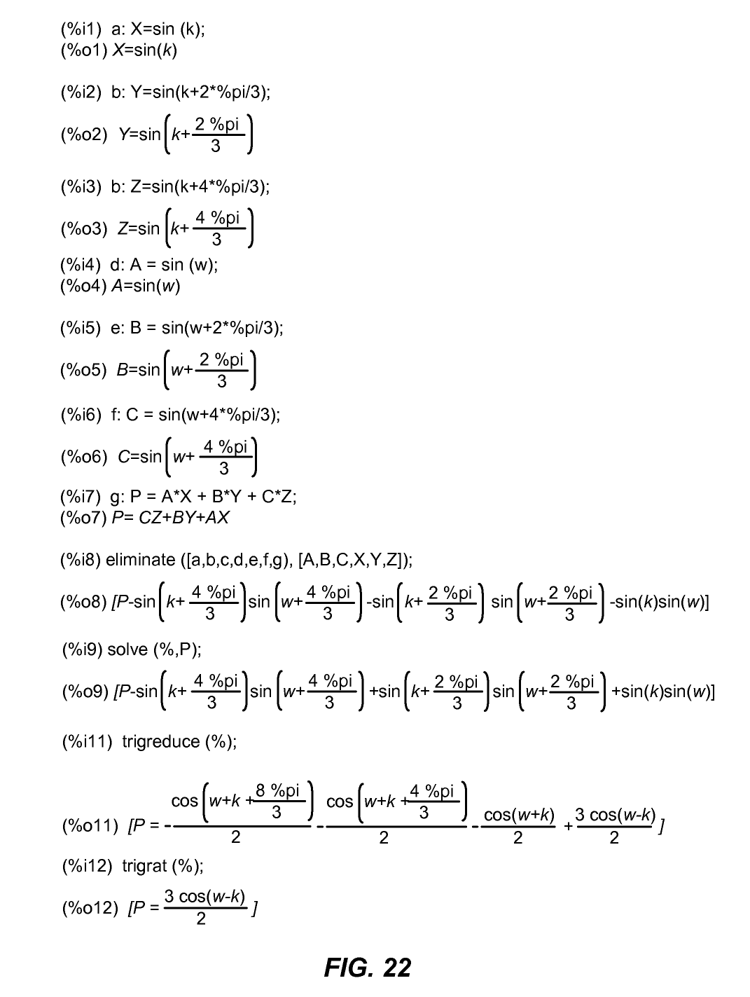

The sine wave 1 and sine wave 2 are those sine waves that would emerge from the operation P=A·X+B·Y+C·Z if X, Y, and Z were held fixed. In the Maxima output of FIG. 22, the P is just 3/2*cos(w−k), so if k=0 then P=3/2*cos(w), and the phase changes with k. In a specific example, at time 0, k=0, then at time 1, k=d, then at time 2, k=2d etc. In this case, sinusoidal wave 1 is just cos(w), sinusoidal wave 2 is just cos(w+d), the next cos(w+2d), etc.

The practical implementation applies to both the generation of the (w2−w1) components which remain after multiplication and addition of the w1 and w2 components, and the generation of the (w2+w1) components which remain after multiplication and addition of the w1 and w2 components. In the embodiment that generates the (w2−w1) components, the X, Y and Z are created as sin(k), sin(k+120) sin(k+240) and as time progresses k is incremented by d. In the embodiment that generates the (w2−w1) components, the logic simply decrements k by d rather than increment it.

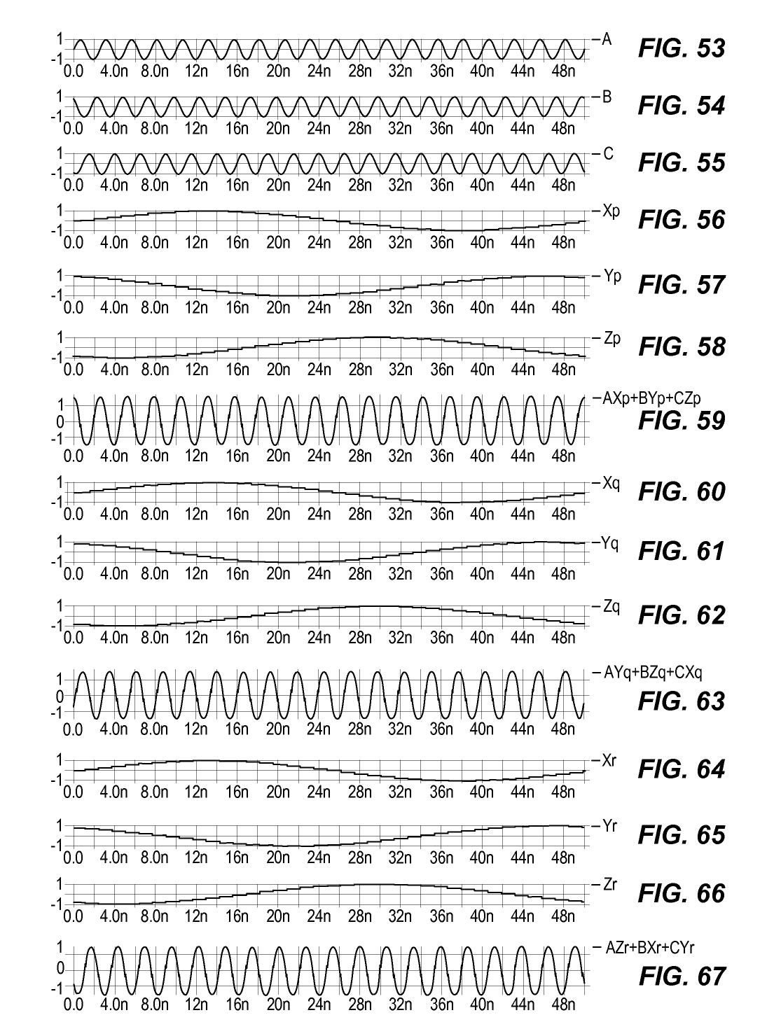

FIGS. 53-67 show examples of input and output signals for the direct digital synthesis circuit without a filter, such as the circuit of FIG. 11.

FIGS. 53-55 show a first multi-phase sinusoid input A B C corresponding to a direct digital synthesis circuit without a filter, such as the circuit of FIG. 11.

FIGS. 56-58 shows a second multi-phase imperfect sinusoid input Xp Yp Zp corresponding to a direct digital synthesis circuit without a filter, such as the circuit of FIG. 11.

FIG. 59 shows an imperfect sinusoid output P from the sum of the partial products AXp BYp CZp, corresponding to a direct digital synthesis circuit with a filter, such as the circuit of FIG. 11.

FIGS. 60-62 shows a second multi-phase imperfect sinusoid input Xq Yq Zq corresponding to a direct digital synthesis circuit without a filter, such as the circuit of FIG. 11.

FIG. 63 shows an imperfect sinusoid output Q from the sum of the partial products AYq BZq CXq, corresponding to a direct digital synthesis circuit with a filter, such as the circuit of FIG. 11.

FIGS. 64-66 shows a second multi-phase imperfect sinusoid input Xr Yr Zr corresponding to a direct digital synthesis circuit without a filter, such as the circuit of FIG. 11.

FIG. 67 shows an imperfect sinusoid output R from the sum of the partial products AZr BXr CYr, corresponding to a direct digital synthesis circuit with a filter, such as the circuit of FIG. 11.

In one embodiment, the analog phase shift oscillator (e.g., with inverters) is the generator of the higher frequency input, and the DDS circuitry is the generator of the lower frequency input. When three inverters (or inverting amplifiers) are placed in a ring the 120 deg phase differences appear. Now that ring can be locked to a multiple of a clock, by, for example, injection locking, or an integer PLL. An integer PLL has the VCO (the three inverters) divided by an integer (say N) and made equal in frequency to the clock. In such a PLL the ring is N*Clk, thereby not requiring a special variable modulus or Sigma delta based divider. Consequently, such circuits can make the ABC signals at N*Clk. However, such circuits fail to generate for example, 12.345678*Clk, since 12.345678 is not a simple factor. With this technology, XYZ need only be 0.345678*Clk and the output will become (12+0.345678)*Clk.

One embodiment makes a very high resolution multiple of a clock. ABC is arranged to be the integer part of that resolution multiples by the clock. The XYZ is the fractional part. For example, in one circuit the clock is 30 Mhz and a desired clock is about 400 Mhz. So ABC is 13*30 Mhz=390 Mhz and XYZ is 10 Mhz, added by the circuit to make 400 Mh output. In some embodiments (ie ABC integer part, XYZ fractional part) XYZ never need exceed ½ Clk—since various embodiments can add or subtract.

### CONCLUSION

The disclosed technology shows how artifact-free frequency shifting is achieved in multiphase signals of three or more elements having equal phase differences. The invention uses the expression of FIG. 4 where X and Y are sets of input signals of N elements, Z is a set of N elements considered as the output, and the index operation i+j is modulo N. The output Z is shown to represent a multiphase signal at a frequency equal to the difference (or sum) of the frequencies of X and Y. Whether the sum or difference is created depends upon the sign of the phase difference of the Xi and Yi. For example, X0 may be 0 degrees, X1 120 degrees, and X2 240 degrees. Or, X0 may be 0 degrees, X1 240 degrees and X2 120 degrees. In the latter case the X signal is considered to be negative. Implementation of the technology in two electronic systems is shown. One uses a DDS. Another uses a modified filter-less DDS. Finally, the output multiphase signal may be gated to create a signal phase and higher speed signal. This latter feature benefits from having an odd number of multiphase signals.

### APPENDIX A

Maxima batch file showing trigonometric identities

These commands executed in the Maxima symbolic math program demonstrate the operation of the frequency shifter.

eqA: A=sin(w[1])$

eqB: B=sin(w[1]+%pi*2/3)$

eqC: C=sin(w[1]+%pi*4/3)$

eqX: X=sin(w[2])$

eqY: Y=sin(w[2]+%pi*2/3)$

eqZ: Z=sin(w[2]+%pi*4/3)$

eqP: P=A*X+B*Y+C*Z$

eqQ: Q=A*Y+B*Z+C*X$

eqR: R=A*Z+B*X+C*Y$

declare (w,real)$

solP:

first(solve(trigrat(trigreduce(eliminate([eqP,eqA,eqB,eqC,eqX,eqY,eqZ],[A,B,C,X,Y,Z]))),P));

solQ:

first(solve(trigrat(trigreduce(eliminate([eqQ,eqA,eqB,eqC,eqX,eqY,eqZ],[A,B,C,X,Y,Z]))),Q));

solR:

first(solve(trigrat(trigreduce(eliminate([eqR,eqA,eqB,eqC,eqX,eqY,eqZ],[A,B,C,X,Y,Z]))),R));

angP: subst(z,w[2]-w[1],solP);

angQ: subst(z,w[2]-w[1],solQ);

angR: subst(z,w[2]-w[1],solR);

subst(z+% pi*2/3,z1,trigrat(subst(z1−%pi*2/3,w[2]−w[1],solQ)));

subst(z−%pi*2/3,z2,trigrat(subst(z2+%pi*2/3,w[2]−w[1],solR)));

1. An apparatus, comprising:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency different from the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a difference of the first common frequency and the second common frequency, and the phase delay corresponding to the number of clock signals evenly separating the third plurality of clock signals, wherein output components having a frequency equal to a sum of the first common frequency and the second common frequency are mutually canceled in the multiplication and addition circuitry.

2. The apparatus of claim 1, wherein the second clock circuitry is a direct digital synthesis circuit with a filter removing higher frequencies from the second plurality of clock signals.

3. The apparatus of claim 1,
wherein the multiplication and addition circuitry includes a zero crossing detector controlled by the multiplication circuitry, and
wherein, responsive to the zero crossing detector, the second clock circuitry changes the second plurality of clock signals.

4. The apparatus of claim 1,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

5. The apparatus of claim 1,
wherein the first clock circuitry is an analog phase shift oscillator,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

6. The apparatus of claim 1,
wherein the first clock circuitry is an analog phase shift oscillator, the first common frequency is less than the second common frequency,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

7. The apparatus of claim 1,
wherein the first common frequency generates a first part of the third common frequency being an integer multiple of a reference clock frequency, and
wherein the second common frequency generates a second part of the third common frequency being a fractional multiple of the reference clock frequency.

8. The apparatus of claim 1,
wherein the first clock circuitry is an analog phase shift oscillator, the first common frequency is less than the second common frequency,
wherein the first common frequency generates a first part of the third common frequency being an integer multiple of a reference clock frequency, and
wherein the second common frequency generates a second part of the third common frequency being a fractional multiple of the reference clock frequency.
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

9. An apparatus, comprising:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency different from the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a sum of the first common frequency and the second common frequency, and the phase delay corresponding to the number of clock signals evenly separating the third plurality of clock signals, wherein output components having a frequency equal to a difference of the first common frequency and the second common frequency are mutually canceled in the multiplication and addition circuitry.

10. The apparatus of claim 9, wherein the second clock circuitry is a direct digital synthesis circuit with a filter removing higher frequencies from the second plurality of clock signals.

11. The apparatus of claim 9,
wherein the multiplication and addition circuitry includes a zero crossing detector controlled by the multiplication circuitry, and
wherein, responsive to the zero crossing detector, the second clock circuitry changes the second plurality of clock signals.

12. The apparatus of claim 9,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

13. The apparatus of claim 9,
wherein the first clock circuitry is an analog phase shift oscillator,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

14. The apparatus of claim 9,
wherein the first clock circuitry is an analog phase shift oscillator, the first common frequency is less than the second common frequency,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

15. The apparatus of claim 9,
wherein the first common frequency generates a first part of the third common frequency being an integer multiple of a reference clock frequency, and
wherein the second common frequency generates a second part of the third common frequency being a fractional multiple of the reference clock frequency.

16. The apparatus of claim 9,
wherein the first clock circuitry is an analog phase shift oscillator, the first common frequency is less than the second common frequency,
wherein the first common frequency generates a first part of the third common frequency being an integer multiple of a reference clock frequency, and
wherein the second common frequency generates a second part of the third common frequency being a fractional multiple of the reference clock frequency.
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

17. An apparatus, comprising:
first clock circuitry generating a first plurality of clock signals having a number of clock signals being three or more, the first plurality of clock signals having a first common frequency, and a phase delay corresponding to the number of clock signals evenly separating the first plurality of clock signals;
second clock circuitry generating a second plurality of clock signals having the number of clock signals, the second plurality of clock signals having a second common frequency equal to the first common frequency, and the phase delay corresponding to the number of clock signals evenly separating the second plurality of clock signals;
multiplication and addition circuitry combining the first plurality of clock signals and the second plurality of clock signals to generate as output a third plurality of clock signals having the number of clock signals, the third plurality of clock signals having a third common frequency equal to a sum of the first common frequency and the second common frequency, and half of the phase delay corresponding to the number of clock signals evenly separating the third plurality of clock signals, wherein output components having a zero frequency are mutually canceled in the multiplication and addition circuitry.

18. The apparatus of claim 17, wherein the second clock circuitry is a direct digital synthesis circuit with a filter removing higher frequencies from the second plurality of clock signals.

19. The apparatus of claim 17,
wherein the multiplication and addition circuitry includes a zero crossing detector controlled by the multiplication circuitry, and
wherein, responsive to the zero crossing detector, the second clock circuitry changes the second plurality of clock signals.

20. The apparatus of claim 17,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.

21. The apparatus of claim 17,
wherein the first clock circuitry is an analog phase shift oscillator,
wherein the second plurality of clock signals of the second clock circuitry are generated by a phase accumulator and an amplitude/sinusoid look-up-table,
wherein the multiplication and addition circuitry includes a zero crossing detector controlled by the multiplication circuitry,
wherein, responsive to the zero crossing detector, the second clock circuitry changes the second plurality of clock signals.
